(19) United States
(12) Patent Application Publication
(10) Pub. No.: US 2010/0301338 A1
(43) Pub. Date: Dec. 2, 2010

(54) THIN FILM DEVICE, FLEXIBLE CIRCUIT BOARD INCLUDING THIN FILM DEVICE, AND METHOD FOR MANUFACTURING THIN FILM DEVICE

(75) Inventor: Daisuke ABE, Chino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/783,767

(22) Filed: May 20, 2010

(30) Foreign Application Priority Data
May 26, 2009 (JP) 2009-126730
Apr. 7, 2010 (JP) 2010-088943

(51) Int. Cl. H01L 29/786; H01L 21/20

(52) U.S. Cl. 257/57; 438/482; 257/E29.289; 257/E21.09

(57) ABSTRACT

A thin film device includes: a substrate; an electric field shielding plate formed above the substrate, the electric filed shielding plate having a conductive material; and a thin film element formed on the electric field shielding plate, the, the electric field shielding plate being connected to a potential of any electrode of the thin film element or a ground potential.

The entire disclosure of Japanese Patent Application Nos: 2009-126730, filed May 26, 2009 and 2010-088943, filed Apr. 7, 2010 are expressly incorporated by reference herein.

### BACKGROUND

1. Technical Field

The present invention relates to a thin film device, a flexible circuit board including a thin film device, and a method for manufacturing a thin film device.

2. Related Art

In thin film semiconductor devices such as liquid crystal display devices (LCD) or electroluminescence (EL) display devices, plastic substrates are sometimes used as base substrates for preventing breakdown caused by impacts of dropping or the like, improving flexibility, reducing the weight, etc. As a technology for forming the thin film semiconductor device on the plastic substrate, there is a transfer technology in the related art described below.

A thin film semiconductor device is first formed on a heat-resistive transfer source substrate, and thereafter an element-forming layer (layer to be transferred) in which a thin film element is formed is peeled from the transfer source substrate. The peeled element-forming layer is attached to a plastic substrate as a second transfer substrate, whereby a semiconductor application device is manufactured. Such a transfer technology is described in detail as a “peeling method” or the like in, for example, JP-A-10-125929, JP-A-10-125930, and JP-A-10-125931.

In the transfer technology, since charges accumulate in a release layer, at the interface thereof, or the like in the manufacturing process, the release layer is sometimes charged. The release layer is disposed close to the thin film element formed in the element-forming layer, and the charges accumulating on the charged release layer change the characteristics of the thin film element. As a result, the circuit operation of the thin film element becomes unstable in some cases. For the problem, a technology is disclosed in JP-A-2006-135051 in which a conductive material is imparted to the release layer and the charges are removed from the release layer in the manufacturing process of the thin film semiconductor device.

When the charges are removed from the release layer by the technology in the related art, since the removal of the charges of the release layer is performed in the manufacturing process of the thin film semiconductor device, the charges cannot be removed after the step of peeling the element-forming layer with the release layer. On the other hand, after the step of peeling the element-forming layer with the release layer, there is a step of applying an adhesive on a non-conductive substrate that is likely to be charged and transferring the element-forming layer thereon. In the transfer step, the substrate or the release layer is sometimes charged. When the substrate or the release layer is charged as described above, the charge distribution of the thin film element is changed, making the circuit operation unstable in some cases. For example, when the thin film element is a transistor, the charge distribution of a channel region is changed, changing a threshold value in some cases.

Even when charges do not accumulate in the substrate or the release layer itself in the manufactured thin film semiconductor device, a mounting surface such as a desk on which the thin film semiconductor device is placed is sometimes charged. In this case, the charge distribution of the thin film element is changed by the charged mounting surface or the like, making the circuit operation unstable in some cases.

### SUMMARY

An advantage of some aspects of the invention is to provide a thin film device free from the influence of charge of a release layer, a substrate, a mounting surface, or the like, and whose circuit operation is stable.

A first aspect of the invention is directed to a thin film device including: a substrate; an electric field shielding plate formed above the substrate and having a conductive material; and an active layer formed on the electric field shielding plate and including a thin film element, wherein the electric field shielding plate is connected to a potential of any electrode of the thin film element or a ground potential.

According to such a configuration, since the electric field shielding plate having a conductive material and connected to a potential of any electrode of the thin film element or a ground potential is provided below the active layer including the thin film element, the influence of charge of the release layer, the substrate, a mounting surface, or the like is absorbed by the electric field shielding plate. That is, it is possible to prevent the active layer from being influenced by the charge of the release layer, the substrate, the mounting surface, or the like. This can stabilize the circuit operation of the thin film element.

It is preferable that the active layer includes as the thin film element a plurality of semiconductor elements each having a channel region, and that each of a plurality of the electric field shielding plates is formed corresponding to the channel region.

According to such a configuration, since each of the plurality of electric field shielding plates is formed corresponding to the channel region, it is possible to effectively prevent the channel region of the thin film element from being influenced by the charge of the release layer or the like with the electric field shielding plate having a small area.

It is preferable that each of the plurality of semiconductor elements has a gate electrode corresponding to the channel region, and that each of the plurality of electric field shielding plates is connected to the gate electrode formed corresponding to each of the plurality of electric field shielding plates.

According to such a configuration, since the gate electrode and the electric field shielding plate have the same potential, the potential distribution in a thickness direction in the active layer is eliminated, eliminating the influence on the operation of the thin film element formed in the active layer. This can enhance the drive ability of the thin film element.

It is preferable that each of the plurality of electric field shielding plates is connected to a ground potential.

According to such a configuration, the electric field shielding plate is fixed to a stable ground potential. Even when the charged state of the release layer or the like is abruptly changed, it is possible to prevent the channel region from being influenced and the operation of the thin film element from becoming unstable.

It is preferable that the electric field shielding plate is formed on an entire surface.

According to such a configuration, forming of the electric field shielding plate can be simplified. Moreover, the influence of charge of the substrate, the release layer, a mounting surface, or the like on the thin film element can be eliminated over the entire surface of the thin film element.

It is preferable that the electric field shielding plate is connected to a ground potential.

According to such a configuration, the electric field shielding plate is fixed to a stable ground potential. Even when the charged state of the release layer or the like is abruptly changed, it is possible to prevent the thin film element from being influenced by the change and from becoming unstable in operation.

It is preferable that the thin film device further includes an adhesive layer formed between the substrate and the electric field shielding plate and bonding the substrate and the electric field shielding plate.

According to such a configuration, the substrate and the electric field shielding plate can be semipermanently bonded.

A second aspect of the invention is directed to a flexible circuit board including: any of the foregoing thin film device, wherein the substrate in the thin film device has flexibility.

According to such a configuration, a flexible circuit board having any of the above-described features, for example, the feature of stabilizing the circuit operation of the thin film element can be configured.

A third aspect of the invention is directed to a method for manufacturing a thin film device including: forming a release layer on a transfer source substrate; forming an electric field shielding plate having a conductive material on the release layer; forming, on the electric field shielding plate, an active layer including a thin film element; and giving the release layer energy to cause at least one of interfacial peeling and in-layer peeling to thereby peeling the electric field shielding plate and the active layer from the transfer source substrate, wherein the electric field shielding plate is connected to any potential of the thin film element.

According to such a method, since the forming of, below the active layer including the thin film element, the electric field shielding plate having a conductive material and connected to any potential of the thin film element is provided, a thin film device having the electric field shielding plate that absorbs the influence of charge of the release layer, the substrate, or a mounting surface can be manufactured. That is, it is possible to prevent the active layer in the thin film device manufactured by the method from being influenced by the charge of the release layer, the substrate, or a mounting surface. This can stabilize the circuit operation of the manufactured thin film element.

In the specification, the “thin film device” mainly indicates a thin film transistor (TFT) but may include an active element in other forms and a passive component such as a pixel electrode, a connection pad, a resistance, or a capacitor.

Also in the specification, the “active layer” indicates one or plurality of layers forming the thin film element. The “element-forming layer” is used with the same meaning as the “active layer”. The “layer to be transferred” indicates one or plurality of layers as a target of transfer in the manufacturing process and includes the “active layer” or the “element-forming layer”.

### BRIEF DESCRIPTION OF THE DRAWINGS

The invention will be described with reference to the accompanying drawings, wherein like numbers reference like elements.

FIG. 1 shows a first configuration example of a thin film device including an electric field shielding plate.

FIG. 2 shows a modified example of the first configuration of the thin film device including the electric field shielding plate.

FIG. 3 shows a second configuration example of a thin film device including an electric field shielding plate.

FIGS. 4A to 4E show a method for manufacturing the thin film device including the electric field shielding plate.

FIG. 5 shows a configuration example of an electro-optic device including a thin film device.

FIGS. 6A and 6B show a configuration example of an electronic apparatus including a thin film device.

FIG. 7 explains the configuration conditions of an electric field shielding plate.

FIG. 8 shows equipotential surfaces that may be generated around electric field shielding plates.

### DESCRIPTION OF EXEMPLARY EMBODIMENTS

Embodiments according to the invention will be specifically described according to the following structure with reference to the drawings. The embodiments described below are only examples of the invention and do not limit the technical range of the invention. In the embodiments, a thin film transistor is described as an example of a thin film element. In the drawings, the same component is denoted by the same reference numeral and sign.

1. First Configuration Example of Thin Film Device including Electric Field Shielding Plate

2. Second Configuration Example of Thin Film Device including Electric Field Shielding Plate

3. Method for Manufacturing Thin Film Device including Electric Field Shielding Plate

4. Configuration Example of Electro-Optic Device including Thin Film Device of the Invention

5. Configuration Example of Electronic Apparatus including Thin Film Device of the Invention

### First Embodiment

1. First Configuration Example of Thin Film Device including Electric Field Shielding Plate

The invention relates to a thin film device. The thin film device of the invention is used as, for example, a flexible electro-optic device such as a flexible display device. Specific application examples will be described later.

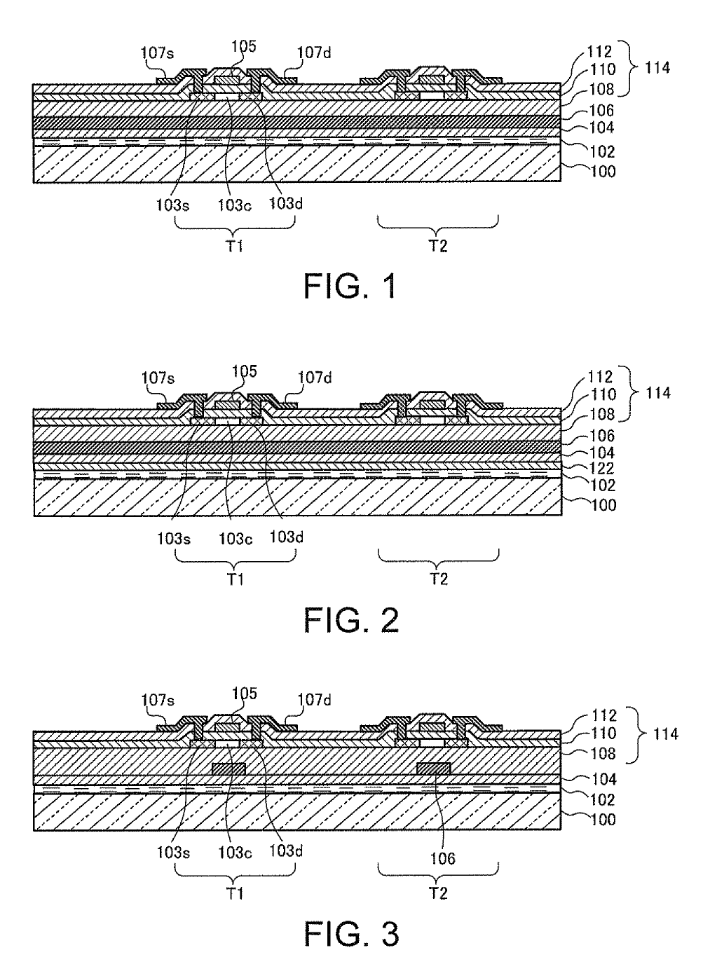

FIG. 1 shows a first configuration example of the thin film device including an electric field shielding plate in a first embodiment of the invention. As shown in FIG. 1, the thin film device in the embodiment is configured to include a plurality of layers. These layers include a substrate 100, an adhesive layer 102, an insulating layer 104, an electric field shielding plate 106, a base insulating layer 108, a gate insulating film 110, and an inter-layer insulating film 112. Among them, the base insulating layer 108, the gate insulating film 110, and the inter-layer insulating film 112 are included in an active layer 114. The active layer 114 also includes thin film transistors T1 and T2. The thin film transistor T1 includes a channel region 103c, a source electrode 103s, a drain electrode 103d, a gate electrode 105, a wiring layer 107s connected to the source electrode 103s, and a wiring layer 107d connected to the drain electrode 103d. Also the thin film transistor T2 includes constituents similar to those of the thin film transistor T1.

### Substrate 100

Since the substrate 100 in the thin film device of the embodiment is bonded after going through a high-temperature process in the manufacturing process, the substrate 100 needs not to be a material capable of resisting a high-temperature process. Accordingly, various materials can be applied to the substrate 100 as usage. For example, a material such as a flexible plastic substrate, inexpensive glass, or ceramic can be used as the substrate 100. Moreover, polyethylene, polypropylene, ethylene-propylene copolymer, or the like can be used as the substrate 100.

### Adhesive Layer 102

The adhesive layer 102 is formed between the substrate 100 and the electric field shielding plate 106 for bonding the substrate 100 and the electric field shielding plate 106. In the embodiment, since the insulating layer 104 is provided below the electric field shielding plate 106, the adhesive layer 102 is formed between the substrate 100 and the insulating layer 104. However, the insulating layer 104 is selectively formed as necessary and is not necessarily formed below the electric field shielding plate 106. As the composition of the adhesive layer 102, a resin such as of epoxy, acrylate, or silicone type is appropriately selected.

### Insulating Layer 104

The insulating layer 104 is formed of an insulator material on the adhesive layer 102. The insulating layer 104 is selectively formed as necessary and is not necessarily formed.

### Electric Field Shielding Plate 106

The electric field shielding plate 106 is directly formed on the insulating layer 104 or the adhesive layer 102. In the embodiment, the electric field shielding plate 106 is formed on the entire surface of the thin film device so as to form one layer. The electric field shielding plate 106 is formed of a conductive material such as a metal and connected to a ground potential of the thin film device. This connection may be made by connecting to any wiring of the thin film transistors formed in the active layer 114. Alternatively, when a casing of an apparatus including the thin film device of the embodiment is at a ground potential, the connection may be made by connecting to the casing. As the composition of the electric field shielding plate 106, a metal or the like having heat resistance so as to be capable of resisting a high-temperature process in the manufacturing process and having a conductive material is used. Chromium (Cr) or molybdenum (Mo) is preferably used.

In addition to chromium and molybdenum, any material can be used as the material of the electric field shielding plate 106 as long as it has a conductive material and is capable of resisting a high-temperature process. For example, aluminum, stainless steel, silver, copper, solder, or other metals or alloys can be applied as the material of the electric field shielding plate 106. Moreover, polythiophene, polypyrrole, polyaniline, polyphenylene vinylene, polyacene, or the like as an organic conductive material is also applicable as the material of the electric field shielding plate 106. Further, a conductive resin containing a material such as polyolefin, fluorinated polymer, thermoplastic elastomer, or silicone rubber as a raw material may be applied as the material of the electric field shielding plate 106.

Further, the material of the electric field shielding plate 106 is preferably selected depending on a process for manufacturing the thin film device. Specifically, since the electric field shielding plate 106 is heated up to about 1000° C. in the manufacturing process of a thin film device using HTPS (high-temperature polysilicon), a material capable of resisting the high temperature, such as chromium or molybdenum, is preferably used as the material of the electric field shielding plate 106. In the manufacturing process of a thin film device using LTPS (low-temperature polysilicon), since it is heated up to about 500° C., a material capable of resisting the temperature, such as aluminum or copper, is preferably used as the material of the electric field shielding plate 106. When a manufacturing method of forming a thin film device at a room temperature is employed, a conductive organic material can be employed as the material of the electric field shielding plate 106.

The electric field shielding plate 106 is configured so as to be able to suppress passing of charges more compared to the base insulating layer 108.

Moreover, the electric field shielding plate 106 is configured such that when the thin film device of the first embodiment is placed on a charged material, and the charged material is disposed under the substrate 100, the electric field strength applied from the charged material to the channel region 103c of the thin film transistor via the base insulating layer 108 is weaker than the electric field strength applied from the gate electrode 105 to the channel region 103c via the gate insulating film 110. For configuring the electric field shielding plate 106 described above, the following mathematical expression needs to be satisfied. In the following mathematical expression, also as shown in FIG. 7, Vg is voltage applied to the gate electrode 105, Dg is the thickness of the gate insulating film 110, ∈g is the relative dielectric constant of the gate insulating film 110, Vb is the absolute value of the potential difference between the channel region 103c and the electric field shielding plate 106, Db is the distance between the channel region 103c and the electric field shielding plate 106, and ∈b is the relative dielectric constant of the base insulating layer 108.

$$\frac{{V}_{g}}{{ɛ}_{g} \cdot {D}_{g}} > \frac{{V}_{b}}{{ɛ}_{b} \cdot {D}_{b}}$$

In the mathematical expression, an element determined by a charged material is the absolute value Vb of the potential difference between the channel region 103c and the electric field shielding plate 106. That is, it is sufficient to configure the electric field shielding plate 106 so as to satisfy the mathematical expression even when the thin film device is placed on a charged material that is conceivably most strongly charged.

The electric field shielding plate 106 is not necessarily formed wholly on the entire surface of the thin film device, and it is sufficient that the electric field shielding plate 106 is formed substantially on the entire surface. As an example of forming the electric field shielding plate 106 substantially on the entire surface, it is conceivable that, for example, the electric field shielding plate 106 is not formed in a region where the thin film transistor is not formed at the outer periphery of the thin film device, but is formed only in the inside portion of the thin film device.

It is preferable that the electric field shielding plate 106 is connected to a ground potential, which is most stable among the potentials of the thin film device. However, this is not restrictive, and the electric field shielding plate 106 may be connected to any electrode in the thin film device.

### Base Insulating Layer 108

The base insulating layer 108 constitutes a basic layer serving as the basis of a thin film transistor. During the manufacture or usage for example, the base insulating layer 108 has at least one of functions as a protective layer that physically or chemically protects the active layer 114, an insulating layer, a barrier layer that stops the migration of a component to the active layer 114 or from the active layer 114, and a reflective layer. As the composition of the base insulating layer 108, various metals can be cited in addition to silicon oxide (SiO₂).

The gate insulating film 110 is formed of an insulator on the base insulating layer 108.

The inter-layer insulating film 112 is formed of an insulator on the gate insulating film 110.

### Active Layer 114

The active layer 114 is configured to include the thin film transistors T1 and T2 on the electric field shielding plate 106.

### Thin Film Transistors T1 and T2

Each of the thin film transistors T1 and T2 is configured to include the source electrode 103s, the drain electrode 103d, the channel region 103c, the gate insulating film 110, the gate electrode 105, the inter-layer insulating film 112, the wiring layer 107s, and the wiring layer 107d.

As described above, the thin film device in the embodiment includes the substrate 100, the electric field shielding plate 106 having a conductive material and formed above the substrate 100, and the active layer 114 formed on the electric field shielding plate 106 and including the thin film elements (thin film transistors). The electric field shielding plate 106 is connected to a potential of any electrode of the thin film element or a ground potential.

According to such a configuration, the electric field shielding plate 106 having a conductive material and connected to any potential of the thin film element or a ground potential is provided below the active layer 114 including the thin film elements. Therefore, the influence of charge of the substrate 100, a mounting surface on which the thin film device is placed, or the like is absorbed by the electric field shielding plate 106. That is, it is possible to prevent the active layer 114 from being influenced by the charge of the substrate 100, the mounting surface, or the like. This can stabilize the circuit operation of the thin film element.

Since the thin film device manufactured by peeling off at the interface of the release layer has been described as an example, the release layer does not remain in the thin film device of the embodiment. In some cases, however, the thin film device is manufactured by peeling off not at the interface of the release layer but in the release layer.

FIG. 2 shows a modified example of the first configuration of the thin film device including the electric field shielding plate of the first embodiment. As shown in FIG. 2, a release layer 122 remains on the adhesive layer 102 in the thin film device. In the manufacturing process in this case, the release layer 122 is sometimes charged. Even in this case, since the release layer 122 is formed below the electric field shielding plate 106, also the influence of charge of the release layer 122 can be absorbed by the electric field shielding plate 106, making it possible to stabilize the circuit operation of the thin film element.

It is preferable that the electric field shielding plate 106 is formed on the entire surface of the thin film device.

According to such a configuration, in the manufacturing process of the thin film device, a step of forming the electric field shielding plate 106 can be simplified. Moreover, the influence of charge of the substrate 100, the release layer 122, a mounting surface, or the like on the thin film element can be eliminated over the entire surface of the thin film element.

It is preferable that the electric field shielding plate 106 is connected to a ground potential.

According to such a configuration, the electric field shielding plate 106 is fixed to a ground potential, which is most stable in the thin film device. Even when the charged state of the substrate 100, the release layer, or the like is abruptly changed, it is possible to prevent the thin film element from being influenced by the change and from becoming unstable in operation.

It is preferable to include the adhesive layer 102 formed between the substrate 100 and the electric field shielding plate 106 and bonding the substrate 100 and the electric field shielding plate 106.

According to such a configuration, the substrate 100 and the electric field shielding plate 106 can be semipermanently bonded. When the insulating layer 104 is formed below the electric field shielding plate 106, the adhesive layer 102 is formed between the substrate 100 and the insulating layer 104.

### Second Embodiment

2. Second Configuration Example of Thin Film Device including Electric Field Shielding Plate

FIG. 3 shows a second configuration example of a thin film device including an electric field shielding plate in a second embodiment of the invention. The first embodiment and the second embodiment in the invention have the same configuration and function except for the electric field shielding plate 106. Therefore, the following description centers around the electric field shielding plate 106.

### Electric Field Shielding Plate 106

As shown in FIG. 3, the electric field shielding plate 106 in the thin film device of the embodiment is not formed on the entire surface of the thin film device but formed partially, unlike the first embodiment.

The active layer 114 is configured to include the thin film transistors T1 and T2. In this case, since the thin film transistors T1 and T2 are configured similarly, the thin film transistor T1 will be described as an example. The thin film transistor T1 has the channel region 103c. When voltage is applied to the gate electrode 105 of the thin film transistor T1, a depletion layer is generated in the channel region 103c formed between the source and drain. When the voltage applied to the gate electrode 105 exceeds a threshold value, the thin film transistor T1 is electrically conducted, whereby current flows between the source electrode 103s and the drain electrode 103d. In this case, when the channel region 103c is influenced by an external voltage or the like, the thin film transistor T1 sometimes operates unexpectedly. For example, when an electric field causing a change in charge distribution is supplied to the channel region 103c of the thin film transistor T1, the threshold voltage of the thin film transistor T1 is changed. Therefore, due to such a trouble that the thin film transistor T1 is electrically conducted with a gate voltage higher than or lower than a designed value, an operational malfunction of a circuit formed of the thin film transistor may occur. Accordingly, for the stable operation of the thin film transistor T1, it is required to configure the thin film transistor T1 such that an external voltage or electric field is not supplied to the channel region 103c.

In the thin film device of the embodiment, therefore, the channel region 103c to which each of the electric field shielding plates 106 corresponds is specified. The electric field shielding plate 106 is formed and disposed for eliminating the influence of voltage, electric field, or the like from the lower side on the corresponding channel region 103c. That is, the electric field shielding plate 106 is formed and disposed below the corresponding channel region 103c.

Specifically, the thin film device in the second embodiment includes the substrate 100, the electric field shielding plate 106 formed above the substrate 100 and having a conductive material, and the active layer 114 formed on the electric field shielding plate 106 and including thin film elements. The electric field shielding plate 106 is connected to a potential of any electrode of the thin film element or a ground potential. The active layer 114 includes as thin film elements a plurality of semiconductor elements (thin film transistors) each having the channel region 103c. Each of the plurality of electric field shielding plates 106 is formed corresponding to the channel region 103c.

According to such a configuration, since each of the plurality of electric field shielding plates 106 is formed corresponding to the channel region 103c, it is possible to prevent the channel region 103c of the thin film element from being influenced by the charge of the substrate 100 or the like with the electric field shielding plate 106 having a small area.

It is preferable that each of the plurality of semiconductor elements (the thin film transistors T1 and T2) has the gate electrode 105 corresponding to the channel region 103c, and that each of the plurality of electric field shielding plates 106 is connected to the gate electrode 105 that is formed corresponding to each of the plurality of electric field shielding plates 106.

In general, the channel region 103c is formed below the gate electrode 105 to which the channel region 103c corresponds.

According to such a configuration, since the gate electrode 105 and the electric field shielding plate 106 have the same potential, the potential distribution in a thickness direction in the active layer 114 is eliminated, eliminating the influence on the operation of the thin film element formed in the active layer 114. This can enhance the drive ability of the thin film element.

The electric field shielding plate 106 is not necessarily connected directly to the corresponding gate electrode 105 but may be indirectly connected thereto so that the electric field shielding plate 106 and the gate electrode 105 corresponding to each other have the same potential. However, it is preferable that the electric field shielding plate 106 and the gate electrode 105 are connected to each other directly. This is because in this case, since the electric field shielding plate 106 has the same potential without delaying a change in voltage of the gate electrode 105, there is almost no time for causing the potential difference between the electric field shielding plate 106 and the gate electrode 105. Therefore, this can stabilize the circuit operation of the thin film element.

Each of the plurality of electric field shielding plates 106 may be connected to a ground potential.

According to such a configuration, the electric field shielding plate 106 is fixed to a stable ground potential. Even when the charged state of the substrate 100, the release layer, or the like is abruptly changed, it is possible to prevent the channel region 103c from being influenced and the operation of the thin film element from becoming unstable.

### Modified Example of Second Embodiment

In the second embodiment, the electric field shielding plate 106 is partially formed below the corresponding channel region 103c as shown in FIG. 3, but this is not restrictive. The electric field shielding plate 106 may be configured in, for example, a mesh form (network form) or a block pattern form. The “block pattern form” indicates a configuration in which, for example, square or rectangular block-like patterns of a predetermined size in a plane view are arranged at a predetermined interval. When the electric field shielding plates 106 in a mesh form or the block pattern form are arranged, an electric field extends to the channel region 103c side at a portion where the electric field shielding plate 106 is not present in a thin film device placed on a charged material. FIG. 8 shows equipotential surfaces 130 around the electric field shielding plates 106 in this case. As also shown in FIG. 8, even the electric field shielding plates 106 configured in the block pattern form at a predetermined interval prevent the channel region 103c from being influenced by an electric field generated by a charged material 120. That is, even when the electric field shielding plates 106 disposed in a mesh form or the block pattern form are used, an effect of shielding (effect of suppressing) the electric field generated by the charged material 120 can be provided.

### Third Embodiment

3. Method for Manufacturing Thin Film Device including Electric Field Shielding Plate

Next, a method for manufacturing the thin film device including the electric field shielding plate of the invention will be described as follows. In the following description, a method for manufacturing the thin film device having the configuration shown in the first embodiment will be first described, and while comparing to the method, a method for manufacturing the thin film device having the configuration shown in the second embodiment will be briefly described.

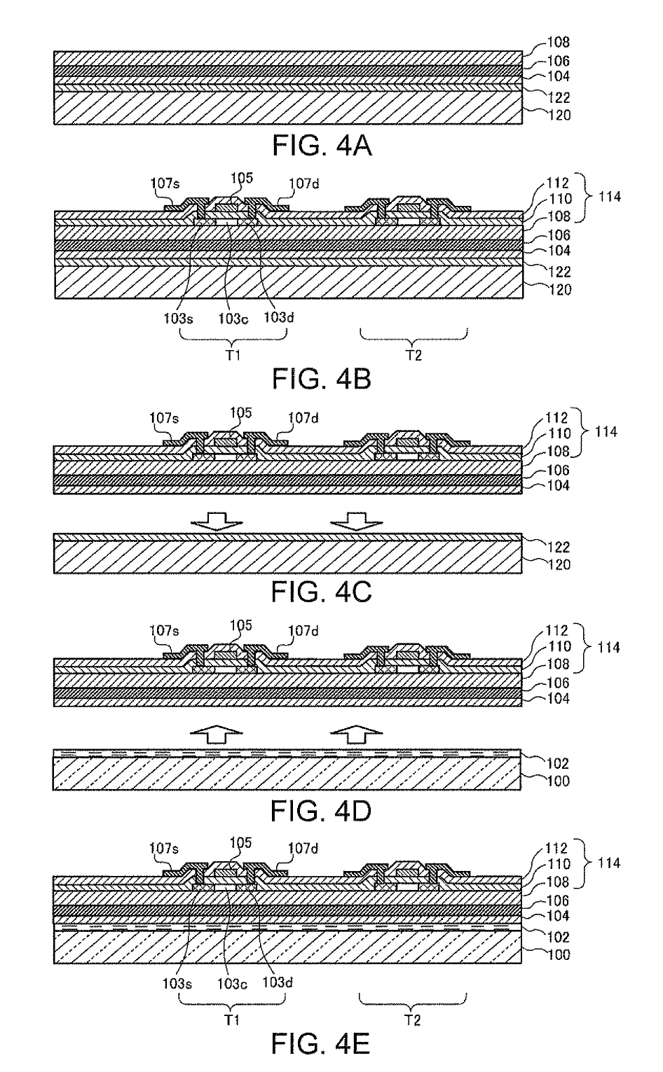

FIGS. 4A to 4E show the method for manufacturing the thin film device including the electric field shielding plate.

As shown in FIG. 4A, the release layer 122 is first formed on a transfer source substrate 120. As the transfer source substrate 120, for example, silica glass or the like is used as a substrate capable of resisting a high-temperature process for manufacturing a thin film transistor.

The release layer 122 has a characteristic of peeling by giving predetermined energy. The “characteristic of peeling” indicates a property that causes peeling in the release layer and/or at the interface thereof (respectively referred to as “in-layer peeling” and “interfacial peeling”) with a laser beam or the like. Specifically, the bonding strength between atoms or molecules of the material constituting the release layer 122 is lost or reduced upon irradiation with light having a constant intensity, that is, ablation or the like occurs, leading to peeling. As the composition of the release layer 122, amorphous silicon (a-Si) or the like is used, for example.

On the release layer 122, the insulating layer 104, the electric field shielding plate 106, and the base insulating layer 108 are sequentially formed. As described in the first embodiment, the insulating layer 104 is not necessarily formed but may be selectively formed as necessary. The electric field shielding plate 106 is connected to a potential of any electrode of the thin film element or a ground potential in any of steps in the manufacturing process.

As shown in FIG. 4B, the thin film transistors T1 and T2 including the gate insulating film 110 and the inter-layer insulating film 112 are next formed on the base insulating layer 108. Each of the thin film transistors T1 and T2 is configured to include the source electrode 103s, the drain electrode 103d, the channel region 103c, the gate insulating film 110, the gate electrode 105, the inter-layer insulating film 112, the wiring layer 107s, and the wiring layer 107d. The base insulating layer 108 and the thin film transistors T1 and T2 constitute the active layer 114.

Although not shown in the drawing in this case, a method of forming a second adhesive layer, a second release layer, and a second substrate on the active layer 114 can also be used. Specifically, a method in the related art as disclosed in JP-A-2006-135051, or the like is used.

As shown in FIG. 4C, energy is next given to the release layer 122, causing the interfacial peeling or in-layer peeling for the release layer 122. Thus, a layer to be transferred, which includes the electric field shielding plate 106 and the active layer 114, is peeled from the transfer source substrate 120. Both the interfacial peeling and the in-layer peeling may be caused for the release layer 122.

As shown in FIG. 4D, instead of the peeled transfer source substrate 120, the substrate 100 is next bonded to the layer to be transferred, which includes the electric field shielding plate 106 and the active layer 114, via the adhesive layer 102.

The substrate 100 is used as a permanent substrate mounted on a final product, and those inferior in heat resistance or in corrosion resistance to the transfer source substrate 120 can be used therefor. Further, those having low rigidity, flexibility, or elasticity may also be adopted as usage.

Through the above-described steps, the thin film device described in the first embodiment can be manufactured as shown in FIG. 4E.

According to such a method, the step of forming, below the active layer 114 including the thin film element, the electric field shielding plate 106 having a conductive material and connected to any potential of the thin film element is provided. Therefore, the electric field shielding plate 106 that absorbs the influence of charge of the release layer 122, the substrate 100, or a mounting surface can be formed. That is, the active layer 114 in the thin film device manufactured by the method can be prevented from being influenced by the charge of the release layer 122, the substrate 100, or a mounting surface. This can stabilize the circuit operation of the manufactured thin film element.

After the step of peeling the electric field shielding plate 106 and the active layer 114 as the layer to be transferred, a step of bonding the substrate 100 to the layer to be transferred can be provided.

In the above description, the method for manufacturing the thin film device shown in the first embodiment in which the electric field shielding plate 106 is formed on the entire surface has been described. The method is applicable to a method for manufacturing the thin film device shown in the second embodiment in which the electric field shielding plate 106 is partially formed. That is, in the thin film device shown in the second embodiment where the active layer 114 includes as thin film elements the plurality of semiconductor elements (thin film transistors) each having the channel region 103c and each of the plurality of electric field shielding plates 106 is formed corresponding to the channel region 103c, in the step of forming the electric field shielding plate 106, the electric field shielding plate 106 is formed not on the entire surface of the thin film device but only at a predetermined portion. Specifically, each of the plurality of electric field shielding plates 106 is formed below the corresponding channel region 103c.

In the manufacturing process, a step of connecting each of the plurality of electric field shielding plates 106 to the gate electrode 105 formed corresponding to each of the electric field shielding plates 106 can be provided. The step can be included in the step of forming the active layer 114.

### Fourth Embodiment

4. Configuration Example of Electro-Optic Device including Thin Film Device of the Invention

Next, a configuration example of an electro-optic device including the above-described thin film device will be described.

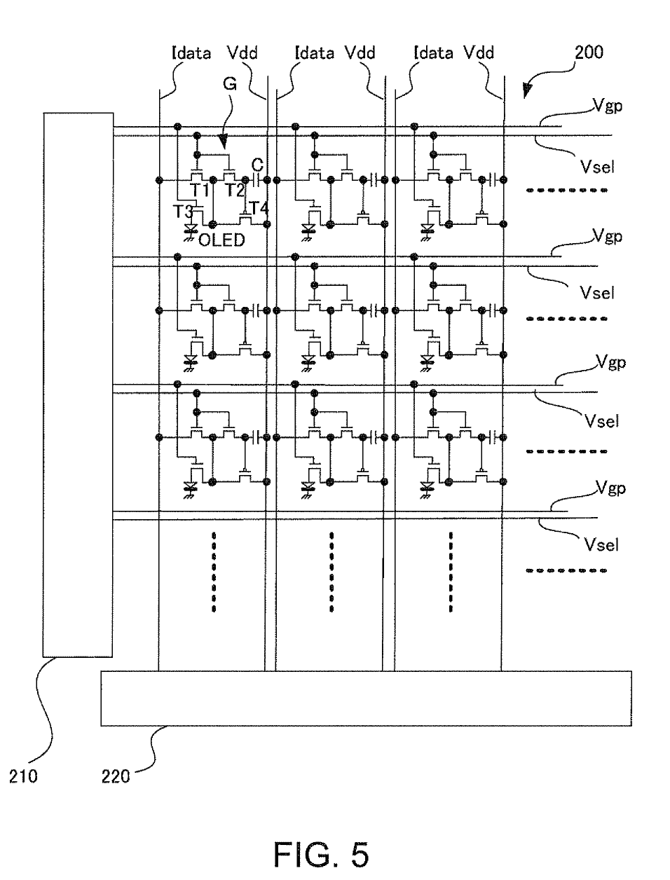

FIG. 5 shows the configuration example of the electro-optic device including the thin film device of the invention. As shown in FIG. 5, in the electro-optic device 200 of the embodiment, each of pixels G is configured to include thin film transistors T1 to T4 including the thin film transistors T1 and T2, an organic electroluminescence element OLED electrically connected to the thin film transistors T1 to T4, and a capacitor C. These pixels G are connected in a matrix with scanning lines Vgp and row select lines Vsel that are wired in a row direction and power-supply lines Vdd and data lines Idata that are wired in a column direction. A scanning driver 210 supplies a scanning control signal to the scanning line Vgp and a row select signal to the row select line Vsel. A current driver 220 supplies a power-supply voltage to the power-supply line Vdd and a data signal to the data line Idata. When both the scanning line Vgp and the data line Idata are in a selected state, current from the power-supply line Vdd flows in the electro-optic device 200 through the organic electroluminescence element OLED.

The electro-optic device 200 includes the thin film device of the invention. The scanning driver 210 and the current driver 220, the scanning lines Vgp, the row select lines Vsel, the power-supply lines Vdd, and the data lines Idata that are formed in a matrix from the drivers, and the thin film transistors T1 to T4 and the capacitor C that are formed in each of the pixels G surrounded by the wires are formed as the active layer 114.

According to the fourth embodiment, since an electro-optic device including the thin film device of the invention is configured, an electro-optic device in which the circuit operation of the thin film element is stable can be provided.

### Fifth Embodiment

5. Configuration Example of Electronic Apparatus including Thin Film Device of the Invention

Next, an electronic apparatus including the above-described thin film device will be described.

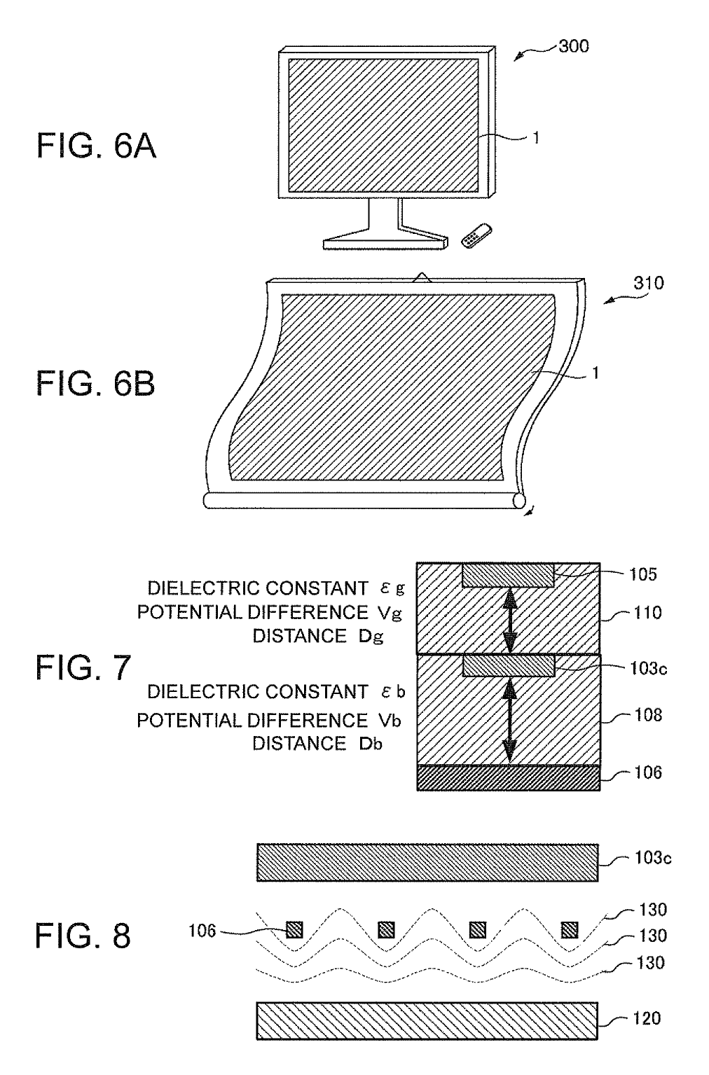

FIGS. 6A and 6B show a configuration example of the electronic apparatus including the thin film device of the invention. The electronic apparatus includes the electro-optic device shown in FIG. 5, for example.

FIG. 6A shows an example in which the thin film device of the invention is applied to a television apparatus 300. The electronic apparatus is configured to include the electro-optic device 200 of the fourth embodiment of the invention.

By including the thin film device of the invention as described above, an electronic apparatus having a feature of, for example, stabilizing the circuit operation of the thin film element can be provided.

FIG. 6B shows an example in which the thin film device of the invention is applied to a roll-up type television apparatus 310. In the roll-up type television apparatus 310, the substrate 100 constituting the thin film device is formed of a flexible material.

That is, the roll-up type television apparatus 310, which includes any of the thin film devices described above, is configured to include a flexible circuit board having a feature that the substrate 100 in the thin film device is flexible.

Since the flexible circuit board of the embodiment includes the flexible substrate 100, the flexible circuit board having any of the above-described features, for example, the feature of stabilizing the circuit operation of the thin film element can be provided. Moreover, like the roll-up type television apparatus 310 including the flexible circuit board, an electronic apparatus having flexibility and the feature of, for example, stabilizing the circuit operation of the thin film element can be provided.

While the embodiments of the invention have been described, the embodiments are only examples of the invention, and the invention is not limited to the embodiments. That is, the invention can be variously modified within a range not departing from the gist thereof and includes those examples appropriately modified based on the embodiments. The embodiments can be combined together within a range not causing inconsistency. For example, the release layer 122 can be included in the thin film device of the second embodiment.

What is claimed is:

1. A thin film device comprising:
a substrate;
an electric field shielding plate formed above the substrate and the electric filed shielding plate having a conductive material; and
a thin film element formed on the electric field shielding plate, the electric field shielding plate being connected to a potential of any electrode of the thin film element or a ground potential.

2. The thin film device according to claim 1, the thin film element including a semiconductor element having a channel region, and the electric field shielding plate being formed corresponding to the channel region.

3. The thin film device according to claim 2,
the semiconductor element having a gate electrode corresponding to the channel region, and
the electric field shielding plate being connected to the gate electrode formed corresponding to the electric field shielding plate.

4. The thin film device according to claim 2,
the electric field shielding plate being connected to a ground potential.

5. The thin film device according to claim 1,
the electric field shielding plate being formed entirely corresponding the substrate.

6. The thin film device according to claim 1,
the electric field shielding plate being connected to a ground potential.

7. The thin film device according to claim 1, further comprising:
an adhesive layer formed between the substrate and the electric field shielding plate, the adhesive layer bonding the substrate and the electric field shielding plate.

8. A flexible circuit board comprising:
the thin film device according to claim 1,
the substrate of the thin film device being flexible.

9. A method for manufacturing a thin film device comprising:
forming a release layer on a transfer source substrate;
forming an electric field shielding plate having a conductive material on the release layer;
forming, on the electric field shielding plate, an active layer including a thin film element; and
giving the release layer energy to cause at least one of interfacial peeling and in-layer peeling to thereby peeling the electric field shielding plate and the active layer from the transfer source substrate,
the electric field shielding plate being connected to a potential of any electrode of the thin film element or a ground potential.
